(19) United States
(12) Patent Application Publication
(10) Pub. No.: US 2024/0355588 A1
(43) Pub. Date: Oct. 24, 2024

(54) SUBSTRATE PROCESSING SYSTEM INCLUDING RF MATCHING CIRCUIT FOR MULTI-FREQUENCY, MULTI-LEVEL, MULTI-STATE PULSING

(71) Applicant: LAM RESEARCH CORPORATION, Fremont, CA (US)

(72) Inventor: Seyed Jafar JAFARIAN-TEHRANI, Fremont, CA (US)

(21) Appl. No.: 18/682,021

(22) PCT Filed: Aug. 3, 2022
(86) PCT No.: PCT/US2022/039292

§ 371 Date: Feb. 7, 2024

Related U.S. Application Data
(60) Provisional application No. 63/233,087, filed on Aug. 13, 2021.

(51) Int. Cl. H01J 37/32; H03H 7/38

(52) U.S. Cl. CPC H01J 37/32183; H03H 7/38

(57) ABSTRACT

An RF matching network connected to an RF generator of a plasma processing system includes a first RF matching circuit configured to receive an output of a first RF source operating at a first RF frequency. A second RF matching circuit is configured to receive an output of a second RF source operating at a second RF frequency that is greater than the first RF frequency. The second RF matching circuit includes an impedance transforming circuit configured to operate above resonance and to alter a slope of a tuning space of the second RF matching circuit to reduce reflected power. An RF output node communicates with the first RF matching circuit, the second RF matching circuit and an electrode located in a processing chamber of the plasma processing system.

### CROSS-REFERENCE TO RELATED APPLICATIONS

This application claims the benefit of U.S. Provisional Application No. 63/233,087, filed on Aug. 13, 2021. The entire disclosure of the application referenced above is incorporated herein by reference.

### FIELD

The present disclosure relates to substrate processing systems and more particularly to RF matching circuits for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are typically used to perform treatments on substrates such as semiconductor wafers. The substrate is typically arranged in a processing chamber including a substrate support such as an electrostatic chuck (ESC). Examples of substrate treatments include deposition, etching, cleaning and/or other processes. Etching usually includes either wet chemical etching or dry etching. Dry etching may be performed using plasma generated by capacitively-coupled plasma (CCP) or inductively-coupled plasma (ICP). Process gas mixtures are supplied and RF plasma power is supplied to ignite the process gases and create plasma in the processing chamber.

During processing, the magnitude and/or frequency of the RF plasma power can be varied to alter the effect of the substrate treatment. In addition, the RF plasma power can be output as a continuous wave and/or pulsed on and off and/or between different non-zero power levels. Changes in the RF plasma power and/or pulsing can cause changes in the impedance seen by the RF drive circuit. In addition, the plasma forms part of the load. As the plasma conditions vary, the impedance of the load varies. When an impedance mismatch occurs between the load and the RF source, power is reflected, which is inefficient.

### SUMMARY

An RF matching network connected to an RF generator of a plasma processing system includes a first RF matching circuit configured to receive an output of a first RF source operating at a first RF frequency. A second RF matching circuit is configured to receive an output of a second RF source operating at a second RF frequency that is greater than the first RF frequency. The second RF matching circuit includes an impedance transforming circuit configured to operate above resonance and to alter a slope of a tuning space of the second RF matching circuit to reduce reflected power. An RF output node communicates with the first RF matching circuit, the second RF matching circuit and an electrode located in a processing chamber of the plasma processing system.

In other features, the electrode is located in a top plate of an electrostatic chuck. The electrode includes a baseplate of an electrostatic chuck. The impedance transforming circuit includes a first impedance including a first terminal connected to the second RF source and a second terminal connected to a reference potential. A second impedance includes a first terminal connected to the second RF source; a third impedance including a first terminal connected to a second terminal of the second impedance and a second terminal connected to a reference potential. A fourth impedance includes a first terminal connected to the second terminal of the second impedance. A fifth impedance includes a first terminal connected to the second terminal of the fourth impedance and a second terminal connected to a reference potential.

In other features, each of the first impedance, the second impedance, the third impedance, the fourth impedance, and the fifth impedance comprise a reactive impedance. The first impedance includes a first inductor; the second impedance includes a first capacitor; the third impedance includes a second capacitor; the fourth impedance includes a second inductor; and the fifth impedance includes a third capacitor.

In other features, the first impedance includes a first inductor; the second impedance includes a first capacitor; the third impedance includes a second capacitor; the fourth impedance includes a third capacitor; and the fifth impedance includes a second inductor.

In other features, the first impedance includes a first inductor; the second impedance includes a first capacitor; the third impedance includes a second capacitor; the fourth impedance includes a second inductor; and the fifth impedance includes a third inductor in series with a third capacitor.

In other features, the first RF matching circuit includes a first inductor including a first terminal connected to the first RF source. A first capacitor including a first terminal connected to a second terminal of the first inductor and a second terminal connected to a reference potential; and a second inductor including a first terminal connected to the second terminal of the first inductor and to the first terminal of the first capacitor.

In other features, the first RF matching circuit further includes a second capacitor connected to a second terminal of the second inductor. A third capacitor is connected to the second terminal of the second inductor. A fourth capacitor is connected to the second terminal of the second inductor and a second terminal of the third capacitor.

In other features, the second RF matching circuit further includes a first capacitor including a first terminal in communication with the impedance transforming circuit and a second terminal in communication with a first terminal of a first impedance.

A plasma generator for the plasma processing system includes the first RF source, the second RF source, the RF matching network and a DC source in communication with the RF output node.

In other features, the second RF source includes an auto-tuning circuit configured to adjust the second RF frequency in a predetermined frequency band about a center frequency to minimize reflected power. A rate of change of a real component of the resistance of the second RF matching circuit relative to a frequency of the second RF source is greater than zero. The center frequency is 60 MHz and the predetermined frequency band is between 57 MHz and 63 MHz.

In other features, a first inductance has a first terminal in communication with the DC source and the first RF matching circuit. A second inductance has a first terminal and a second terminal, wherein the second terminal is connected to the RF output node. A third inductance has a first terminal and a second terminal. The first terminal of the third inductance is in communication with the second RF matching circuit and the second terminal of the third inductance is connected to the first terminal of the second inductance.

A plasma generator for a plasma processing system includes a first RF source operating at a first RF frequency. A first RF matching circuit is configured to receive an output of the first RF source. A second RF source operates at a second RF frequency that is greater than the first RF frequency and including an auto-tuning circuit to adjust the second RF frequency to minimize reflected power. A second RF matching circuit is configured to receive an output of the second RF source and includes an impedance transforming circuit configured to operate above resonance and to provide a rate of change of a real component of the resistance of the second RF matching circuit relative to a frequency of the second RF source that is greater than zero. A RF output node communicates with the first RF matching circuit and the second RF matching circuit and an electrode located in a processing chamber of the plasma processing system. A DC source is in communication with the RF output node.

In other features, the electrode is located in a top plate of an electrostatic chuck. The electrode includes a baseplate of an electrostatic chuck. The impedance transforming circuit includes a first impedance including a first terminal connected to the second RF source and a second terminal connected to a reference potential; a second impedance including a first terminal connected to the second RF source; a third impedance including a first terminal connected to a second terminal of the second impedance and a second terminal connected to a reference potential; a fourth impedance including a first terminal connected to the second terminal of the second impedance; and a fifth impedance including a first terminal connected to the second terminal of the fourth impedance and a second terminal connected to a reference potential. Each of the first impedance, the second impedance, the third impedance, the fourth impedance, and the fifth impedance comprise a reactive impedance.

In other features, the first impedance includes a first inductor; the second impedance includes a first capacitor; the third impedance includes a second capacitor; the fourth impedance includes a second inductor; and the fifth impedance includes a third capacitor.

In other features, the first impedance includes a first inductor; the second impedance includes a first capacitor; the third impedance includes a second capacitor; the fourth impedance includes a third capacitor; and the fifth impedance includes a second inductor.

In other features, the first impedance includes a first inductor; the second impedance includes a first capacitor; the third impedance includes a second capacitor; the fourth impedance includes a second inductor; and the fifth impedance includes a third inductor in series with a third capacitor.

In other features, the second RF matching circuit further includes a first capacitor including a first terminal in communication with the impedance transforming circuit and a second terminal in communication with a first terminal of a first impedance.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including an RF matching circuit for multi-frequency, multi-level, multi-state pulsing according to the present disclosure;

FIG. 2 is an electrical schematic of an example of an RF matching circuit;

FIG. 3 is a graph showing an example of a reflection coefficient as a function of taps for different capacitance values using the RF matching circuit of FIG. 2;

FIG. 4 is a graph of an example of a tuning space of the RF matching circuit (in imaginary and real impedance space) for the RF matching circuit of FIG. 2;

FIG. 5 is an electrical schematic of an example of an RF matching circuit according to the present disclosure;

FIG. 6 is a graph showing various tuning spaces for RF matching circuits (in imaginary and real impedance space) for the RF matching circuit of FIG. 2 and example implementations of the circuit of FIG. 5;

FIG. 7 is an electrical schematic of an example of an RF matching circuit according to the present disclosure;

FIG. 8 is an electrical schematic of another example of an RF matching circuit according to the present disclosure; and

FIG. 9 is an electrical schematic of another RF example of an RF matching circuit according to the present disclosure.

In the drawings, reference numbers may be reused to identify similar and/or identical elements.

### DETAILED DESCRIPTION

During processing of substrates, RF plasma power may be supplied to an electrode of an electrostatic chuck (ESC) to promote chemical reactions. When multi-frequency, multi-level, multi-state RF pulsing is used, the plasma impedance will be different depending upon the selected RF plasma power state. While specific examples of frequencies and/or power levels will be described in the following examples, other frequencies and/or power levels can be used. In some examples, first and second RF sources may be used to supply RF power at two or more frequencies to electrodes in the ESC. The RF power can be supplied as a continuous wave (CW) and/or one or more pulsing modes. Non-limiting examples of pulsing modes include pulsing at on and off or at two or more different, non-zero magnitudes at 1 KHz, 2 KHz, 3 KHz or other pulsing frequencies.

For example, the first RF source may operate at 400 KHz and the second RF source may operate at 60 MHZ, although other frequencies may be used during substrate treatments. The first and second RF power sources 123, 125 may be operated at multiple power states. For example, three power states S0, S1 and S2 may be used. In this example, the power state S0 may correspond to operation using only the second RF power source. The power state S1 may correspond to operation using both the first RF power source and the second RF power source at first and second power levels, respectively. The power state S2 may correspond to operation using both the first RF power source and the second RF power source at third and fourth power levels, respectively. In some examples, the first, second, third and fourth power levels are different. In other examples, the second and fourth power levels of the second RF power source are the same for the power states S1 and S2.

Higher frequencies tend to have higher power transfer efficiency in terms of etch rate and film quality. Lower power states tend to operate at higher reflected power (5-20%), which reduces power transfer efficiency. Generally, the RF matching network is designed to minimize reflected power for all of the power states. The RF matching circuits may incorporate variable capacitors and/or trim capacitors that can be adjusted for a given application. The capacitor values of the variable capacitors can be adjusted within a few hundred milliseconds using motors. However, the capacitor values cannot be adjusted quickly enough when switching between different power states (such as S0, S1 and/or S2) to reduce reflected power within desired limits. As will be described further below, only frequency change (e.g. to minimize reflected power using auto-tuning) is fast enough to keep up with pulsing transients and peak RF power delivery. However, some RF matching circuits may not be able to sufficiently reduce reflected power using the frequency adjustment provided by auto-tuning.

The present disclosure adds an impedance transforming circuit to the RF matching network to adjust the tuning space and the relationship between real and imaginary parts of the plasma load impedance as a function of auto-tuning frequency range. As a result, the RF matching network reduces reflective power in all operating states. Current RF matching networks operate at greater than or equal to 4-5% reflected power for all power levels and pulsing states. In some examples, the RF matching network according to the present disclosure operates below 1% reflected power at higher power levels at 60 MHz and below 4% reflected power for lower power operation. In some examples, the RF matching circuit according to the present disclosure employs a combination of “T” and/or pi networks to change the slope of the real component of the impedance as a function of auto-tuning frequency range.

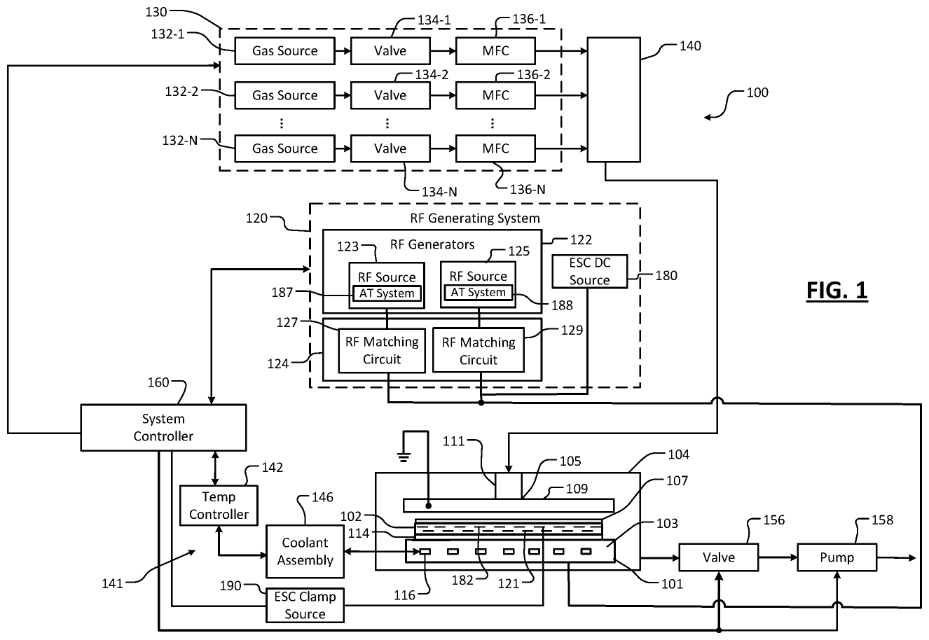

While FIG. 1 shows a capacitive coupled plasma (CCP) system, the embodiments disclosed herein can be used in other types of plasma processing systems. In some examples, a substrate processing system 100 includes an ESC 101 with an ESC top plate 102 and a baseplate 103. The ESC top plate 102 may be made of ceramic and/or other suitable materials and the baseplate 103 may be made of ceramic, aluminum or other material. See correction on FIG. 1 drawing

The substrate processing system 100 includes a processing chamber 104 that contains the RF plasma. The ESC 101 and an upper electrode 105 are located in the processing chamber 104. During operation, a substrate 107 is arranged on and electrostatically clamped to the ESC top plate 102 of the ESC 101.

The upper electrode 105 may include a showerhead 109 that introduces and distributes process and/or purge gases in the processing chamber 104. The showerhead 109 may include a stem portion 111 including one end connected to a top surface of the processing chamber 104. The showerhead 109 is generally cylindrical and extends radially outward from an opposite end of the stem portion 111 at a location that is spaced from the top surface of the processing chamber 104. The showerhead 109 includes an internal gas plenum (not shown). Process or purge gas flows from the plenum into the processing chamber through holes in a substrate-facing surface of the showerhead 109. Alternately, the upper electrode 105 may include a conducting plate and the gases may be introduced in another manner. An intermediate (or bond) layer 114 bonds the ESC top plate 102 to the baseplate 103.

As will be described further below, an RF generating system 120 outputs RF power to electrodes 121 in the ESC top plate 102 and/or to the baseplate 103. In this example, the upper electrode 105 is connected to a reference potential such as ground. In other examples, the RF power can be delivered to the upper electrode 105 and the ESC 101 can be grounded. In another example both top electrode and ESC may be powered.

Power from the RF generating system 120 is fed by a matching network 124 to the lower electrode 121 (or alternately to the baseplate 103) of the ESC 101. The RF generating system 120 includes a first RF source 123 operating at a first frequency and a second RF source 125 operating at a second frequency. The matching network 124 includes a first RF matching circuit 127 connected to the first RF source 123 and a second RF matching circuit 129 connected to the second RF source 125, respectively. As will be described further below, the second RF matching circuit 129 includes an impedance transforming circuit that operates above resonance and adjusts the tuning space of the second RF matching circuit as will be described further below.

A gas delivery system 130 includes one or more gas sources 132-1, 132-2, . . . , and 132-N (collectively gas sources 132), where N is an integer greater than zero. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 104 via the showerhead 109.

The substrate processing system 100 may include a cooling system 141 that includes a temperature controller 142. Although shown separately from a system controller 160, the temperature controller 142 may be implemented as part of the system controller 160. The temperature controller 142 communicates with a coolant assembly 146 including a coolant pump and reservoir (both not shown). The temperature controller 142 controls flow of coolant through the channels 116. A valve 156 and pump 158 may be used to evacuate reactants from the processing chamber 104.

The system controller 160 controls components of the substrate processing system 100 including RF power levels, gas flow rates, etc. The system controller 160 may also control the valve 156 and the pump 158 to control pressure in the processing chamber.

In some examples, both RF sources 123 and 125 include auto-tuning circuit 187 and 188, respectively, that monitor reflected power using one or more sensors (not shown). The auto-tuning circuits 187 and 188 automatically adjust the frequency of the RF sources 123 and 125, respectively, in a frequency band around a center frequency of each RF sources. For example only, the second RF source 125 may operate at a center frequency of 60 MHz and may have an adjustable frequency band between 57 MHz and 63 MHZ, although other center frequencies and/or frequency bands may be used. The auto-tuning circuit 188 automatically adjusts the RF frequency within the adjustable frequency band to achieve the lowest reflected power. An ESC clamp source 190 may provide DC clamping voltage to a clamping electrode 182 to electrostatically clamp the substrate 107 to the ESC top plate 102. The ESC clamp source 190 may be controlled by the system controller 160.

As ESC DC source 180 provides DC voltages to the electrodes 121 and/or the baseplate 103. In some examples, the ESC DC source 180 supplies a DC bias to ensure that the electrostatic clamping force remains balanced as plasma is struck and is maintained during substrate processing. In some examples, the DC bias is in a range from −500V to −1500V (e.g. −1 kV), although other voltage values can be used.

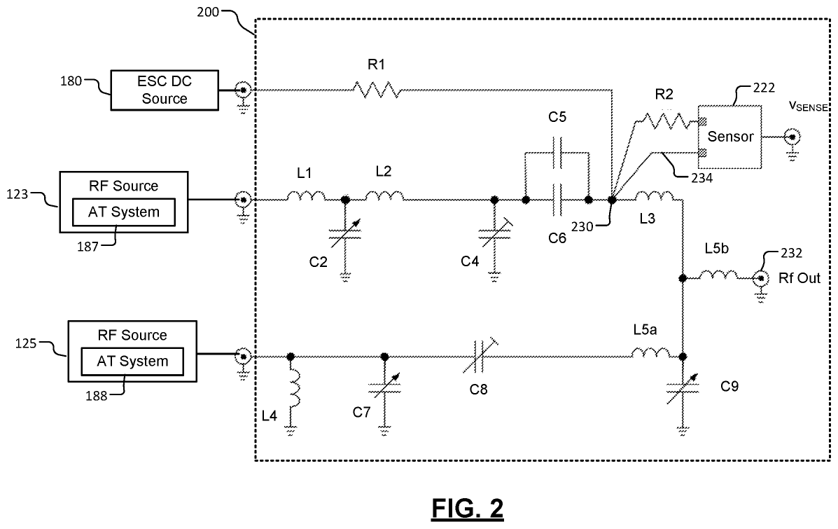

Referring now to FIG. 2, an example of an RF matching circuit 200 is shown. Generally, reactive components of the RF matching circuit 200 are selected to ensure operation below resonance. In some examples, an output of the RF matching circuit 200 is also connected to the ESC DC source 180. The RF matching circuit 200 is connected to the first RF source 123 supplying RF power at the first RF frequency. In some examples, the first RF frequency is in a range from 100 to 600 kHz (e.g. 400 kHz), although other RF frequencies can be used. The RF matching circuit 200 is connected to a second RF source 125 supplying RF power at a second RF frequency. In some examples, the second RF frequency is higher than the first RF frequency and is in a range from 10 MHz to 100 MHz (e.g. 60 MHZ), although other RF frequencies can be used. An RF output node 232 of the RF matching circuit 200 is connected to the baseplate 103 of the ESC or the electrodes 121.

The ESC DC source 180 is connected by a resistor R1 to a node 230. A sensor 222 (connected by a resistor R2 and a conductor 234 to the node 230) senses a voltage Vₛₑₙₛₑ at the node 230. The first RF source 123 is connected to inductors L1 and L2. A motorized variable capacitor C2 has one terminal connected between first terminals of the inductors L1 and L2 and another terminal connected to a reference potential such as ground. A second terminal of the inductor L2 is connected to first terminals of trim capacitor C4, capacitor C5 and capacitor C6. A second terminal of the trim capacitor C4 is connected to a reference potential such as ground. Second terminals of the capacitors C5 and C6 are connected to the node 230. The node 230 is connected to a first terminal of an inductor L3. A second terminal of the inductor L3 is connected to a first terminal of an inductor L5b. A second terminal of the inductor L5b is connected to the RF output node 232.

The second RF source 125 is connected to first terminals of an inductor L4, a variable capacitor C7 and a trim capacitor C8. A second terminal of the trim capacitor C8 is connected to a first terminal of an inductor L5a. A second terminal of the inductor L5a is connected to the second terminal of the inductor L3, the first terminal of the inductor L5b and the first terminal of a variable capacitor C9. A second terminal of the variable capacitor C9 is connected to a reference potential such as ground.

In some examples, the first RF source 123 operates at 400 KHz and has a frequency tuning rage from 340 kHz to 440 KHz and the second RF source 125 operates at 60 MHz and has a frequency tuning range between 57 MHz and 63 MHZ, although other frequencies and frequency bands can be used. Examples of suitable values for the inductor L1, L3, C2, L2, C4, C5, and C6 include 53 μH, 2.2 μH, 40 to 2000 pF, 30 μH, 25-35 pF, 2800 pF and 2800 pF respectively, although other values can be used. Examples of suitable values for the inductor L4, C7, C8, L5a+L5b, and C9 include 0.45 μH, 25 to 250 pF, 10-20 pF, 0.188 μH, and 3-30 pF, respectively, although other values can be used.

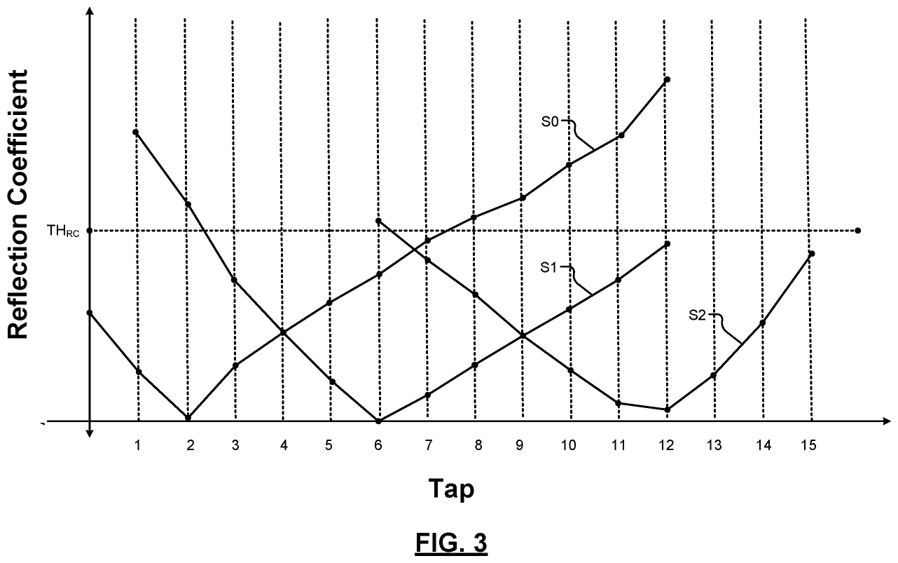

Referring now to FIG. 3, a reflection coefficient is shown as a function of taps for different values of the capacitor C7 and corresponding to output power states S0, S1 and S2 using the RF matching circuit of FIG. 2. The taps represent different capacitor values of one or more of the variable capacitors. In some examples, the variable capacitors include a motor, a first spiral metal portion and a second spiral metal portion that variably overlaps the first spiral portion, although other types of variable capacitors can be used. The motor is used to adjust the amount of overlap to vary the capacitance. Various positions of the motor correspond to the different tap values.

As can be appreciated, a lowest reflected power for the different power states S0, S1 and S2 occurs for different tap values. In FIG. 3, tap 2 corresponds to the minimum reflected power for the power state S0, tap 6 corresponds to the minimum reflected power for the power state S1 and between tap 11 and tap 12 corresponds to the minimum reflected power for power state S3. As was described above, it is not possible to change the taps or capacitor values quickly enough during substrate processing to reduce reflected power sufficiently in a multi-level power and pulsing mode.

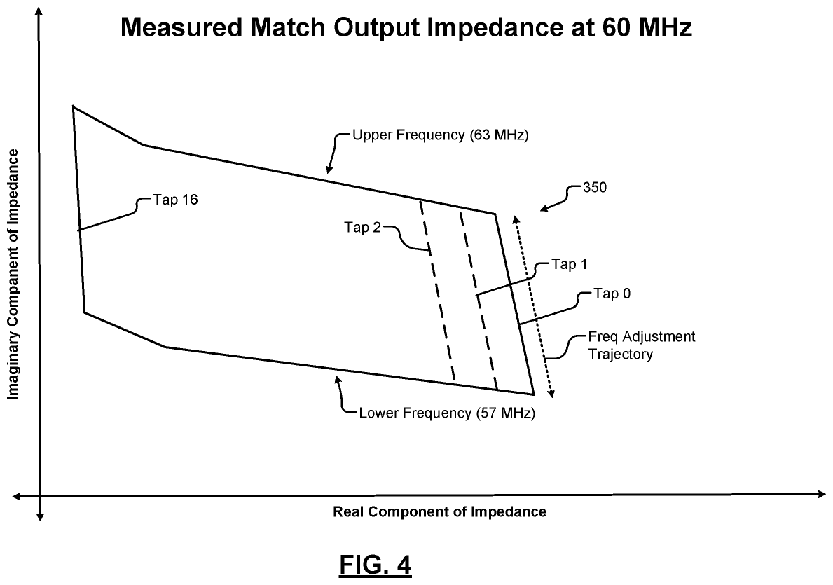

Referring now to FIG. 4, a tuning space 350 for the RF matching circuit of FIG. 2 is shown (real impedance (x-axis) and imaginary impedance (y-axis)). Generally vertical lines correspond to different tap values (which correspond to different capacitor values). An upper generally vertical line in the tuning space 350 corresponds to a maximum tuning frequency of the auto-tuning circuit 188 and a lower generally vertical line corresponds to a minimum tuning frequency of the auto-tuning circuit 188.

During operation, the frequency of the RF source is automatically adjusted vertically along one of the selected tap lines to minimize the reflection coefficient. Note that there is not enough time to change the taps during operation. Generally each of the power states has an ideal matched impedance point (mapped in real and imaginary impedance space) corresponding to the minimum reflected power. However, locations in the tuning space corresponding to lowest reflected power for all of the power states are not sufficiently close to any one of the tap lines to provide sufficiently low overall reflected power.

As can be appreciated, the frequency of the second RF source 125 is adjusted by the auto-tuning circuit 188 very quickly (on the order of milliseconds) as compared to changing the capacitor values of the variable capacitors using motors (on the order of hundreds of milliseconds).

For the matching network in FIG. 2, varying the RF frequency during auto-tuning between the minimum and maximum RF frequency to minimize reflected power predominantly alters the imaginary component of the impedance (in some examples greater than 10Ω of inductive or reactive impedance). However, auto-tuning does not have much impact on the real component of the impedance. As can be seen in FIG. 4, moving along any one of the tap lines (due to changes in RF frequency from minimum to maximum auto-tune frequency) does not change the real component very much (in some examples, the real component changes less than −0.5 Ohms (e.g. about −0.25 Ohm)) as the frequency is increased (due to the very high negative slope of the tap lines).

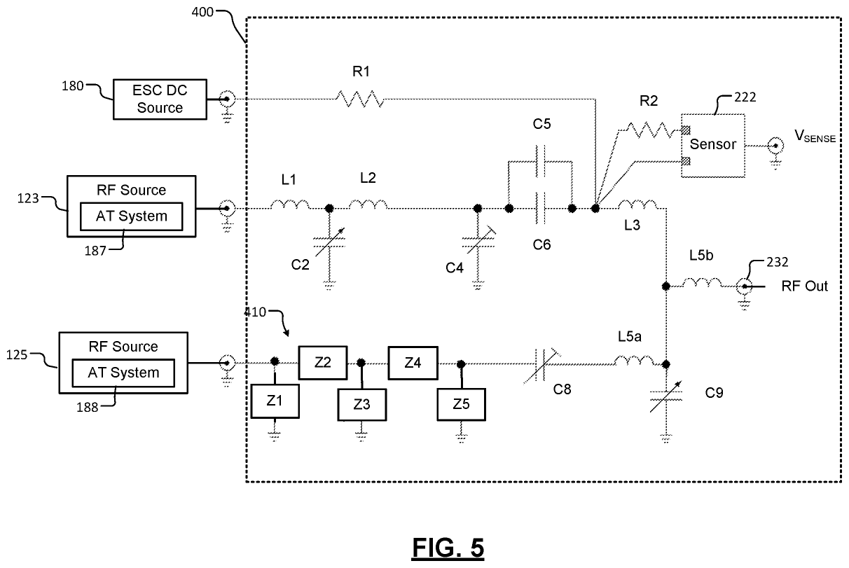

Referring now to FIG. 5, an RF matching circuit 400 includes an impedance transforming circuit 410. The impedance transforming circuit 410 is configured to operate above resonance and to alter a slope of the tap lines between the maximum and minimum RF frequency. The altered slope of the tap lines allows the automatic adjustment of frequency (to reduce reflected power) to have a more significant impact on the real component of the impedance of the RF matching circuit. More particularly, the slope is transformed from a high negative slope to a lower positive slope. Therefore, changing the RF frequency using the auto-tuning circuit 188 allows both the imaginary component and the real component of the impedance to be adjusted in an appreciable manner in a short period of time using a single knob. Furthermore, various operating points on the selected tap line are closer to the ideal matched impedance points for all of the different power states. As a result, the RF matching circuit 400 allows the reflected power to be automatically reduced during operation at the different power states by varying the RF frequency using the auto-tuning circuit 188.

The impedance transforming circuit 410 includes a first impedance Z1, a second impedance Z2, a third impedance Z3, a fourth impedance Z4 and a fifth impedance Z5. Each of the impedances Z1 to Z5 includes one or more reactive components (capacitors and/or inductors) and may include one or more resistors. The components of each of the impedances Z1 to Z5 can be connected in series, parallel and/or combinations thereof. The second RF source 125 is connected to a first terminal of the first impedance Z1 and a first terminal of the second impedance Z2. A second terminal of the first impedance Z1 is connected to a reference potential such as ground. A second terminal of the second impedance Z2 is connected to a first terminal of a third impedance Z3 and a first terminal of a fourth impedance Z4. A second terminal of the third impedance Z3 is connected to a reference potential such as ground. A second terminal of the fourth impedance Z4 is connected to a first terminal of a fifth impedance Z5 and the first terminal of the trim capacitor C8. A second terminal of the fifth impedance Z5 is connected to a reference potential such as ground. A second terminal of the trim capacitor C8 is connected to a first terminal of the inductor L5a. As will be described further below, the impedance transforming circuit 410 having the topology shown in FIG. 5 allows more robust frequency tuning to reduce reflected power.

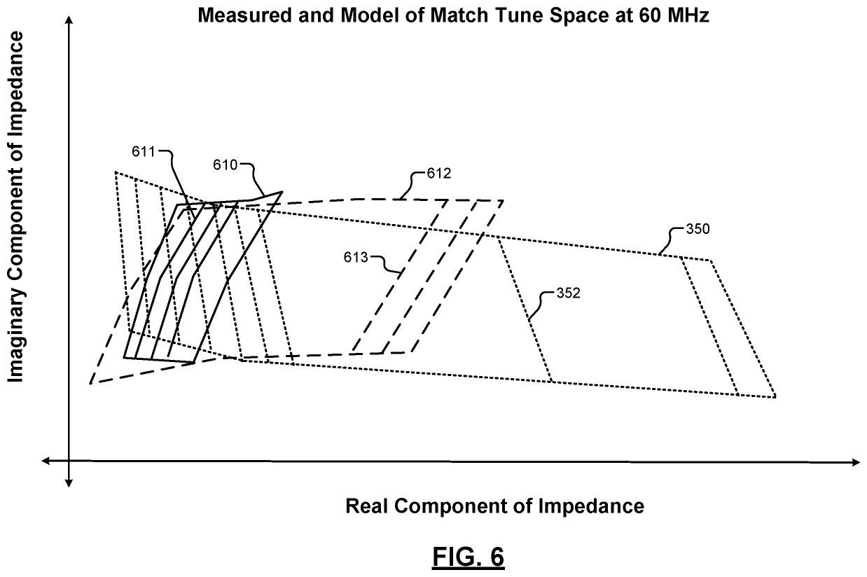

Referring now to FIG. 6, the impedance transforming circuit 410 of FIG. 5 operates above resonance and alters the slope of the tuning space 350 (with some example tap lines 352 shown) corresponding to the RF matching circuit of FIG. 2. Changes in frequency between the maximum and minimum frequency for a given tap line have a bigger impact on the real component of the impedance of the RF matching circuit. As the frequency is increased from a minimum value in the frequency range to the maximum value in the frequency range, the real component and the imaginary component of the resistance increases. In other words, the rate of change of the resistance relative to the frequency (dR/df) is greater than zero (unlike the matching circuit of FIG. 2 where dR/df<0. As a result, the automatic frequency tuning can also be used to reduce reflected power. Examples of tuning space 610 (with some example tap lines 611 shown) and tuning space 612 (with some example tap lines 613 shown) with altered slopes (with respect to real resistance) are shown as will be described further below.

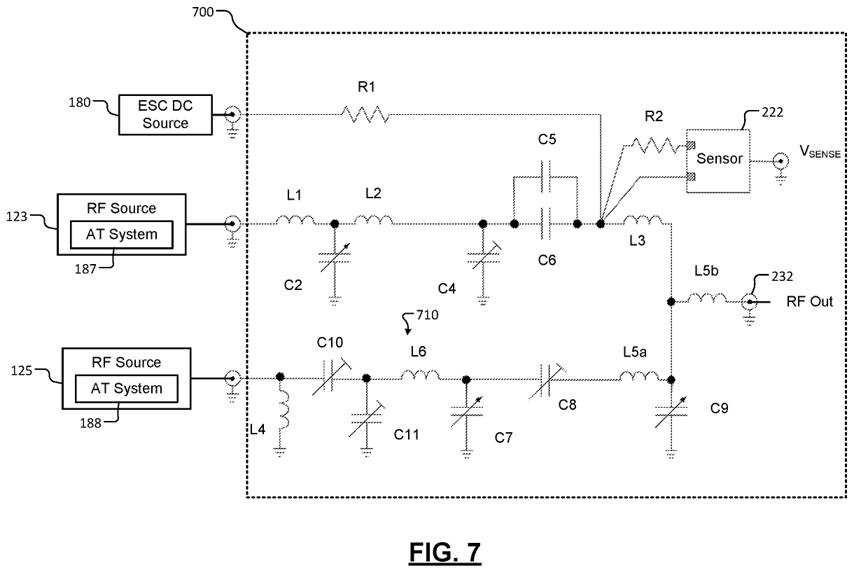

Referring now to FIG. 7, another example of an RF matching circuit 700 including an impedance transforming circuit 710 is shown. In this example, the first impedance Z1 includes an inductor L4, the second impedance Z2 includes a trim capacitor C10, the third impedance Z3 includes a trim capacitor C11, the fourth impedance Z4 includes an inductor L6 and the fifth impedance Z5 includes a trim capacitor C7. As can be appreciated, while fixed, trim and variable capacitors are shown in various circuit locations, fixed, variable or trim capacitors can be used in any of the locations. The tuning space 610 in FIG. 6 corresponds to the RF matching circuit 700. As can be seen, the slope of the tap lines was altered by the impedance transforming circuit 710 from negative to positive and the magnitude of the slope decreased.

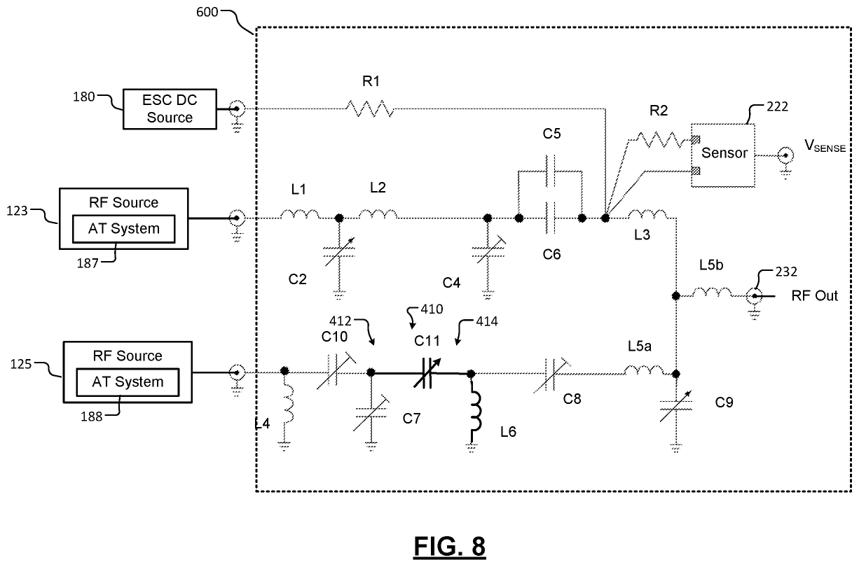

Referring now to FIG. 8, another example of an RF matching circuit 800 including an impedance transforming circuit 810 is shown. In this example, the first impedance Z1 includes an inductor L4, the second impedance Z2 includes a trim capacitor C10, the third impedance Z3 includes an inductor L6, the fourth impedance Z4 includes a trim capacitor C11 and the fifth impedance Z5 includes motorized variable capacitor C7. The impedance transforming circuit 810 alters the slope of the tap lines (to provide dR/df>0) and operates above resonance.

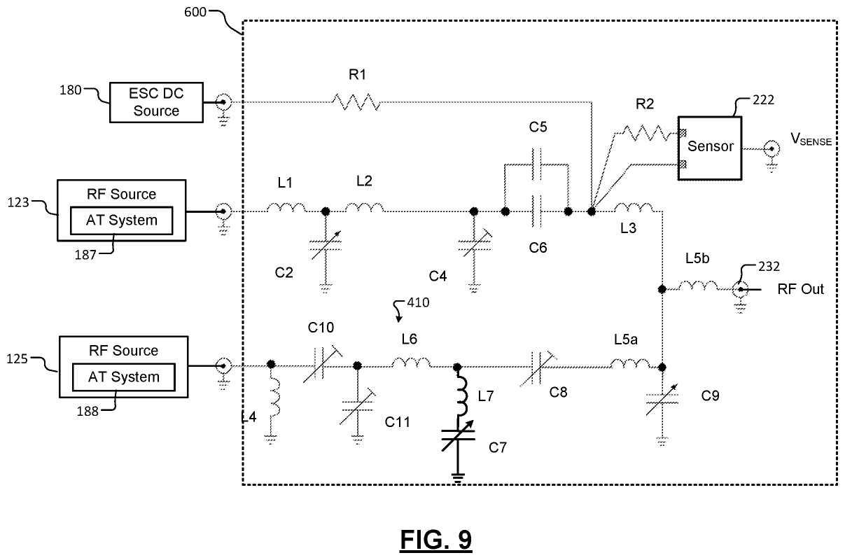

Referring now to FIG. 9, another example of an RF matching circuit 900 including an impedance transforming circuit 910 is shown. In this example, the first impedance Z1 includes the inductor L4, the second impedance Z2 includes the trim capacitor C10, the third impedance Z3 includes the trim capacitor C11, the fourth impedance Z4 includes an inductor L6 and the fifth impedance Z5 includes an inductor L7 in series with the motorized variable capacitor C7. The tuning space 612 in FIG. 6 corresponds to the RF matching circuit 700. As can be seen, the slope of the tap lines was altered from negative to positive and the magnitude of the slope decreased as compared to the tuning spaces 350 and 610. The impedance transforming circuit 810 alters the slope of the tap lines (to provide dR/df>0) and operates above resonance.

In this example, values of the inductor L7 and a lowest value of the variable capacitor C7 are selected to have a resonant frequency below the lowest operating frequency of the second RF source (e.g. 57 MHZ) to ensure operation above the resonance frequency. In addition, a ratio of the values of the second impedance to the third impedance can be used to rotate the tuning space in the imaginary and real resistance space. Examples of suitable values for the inductor L4, C10, C11, L6, L7, C7, C8, L5a+L5b, and C9 include 0.45 μH, 55-65 pF, 25-35 pF, 150 nH, 120 nH, 25 to 250 pF, 10-20 pF, 0.188 μH, and 3-30 pF, respectively, although other values can be used. As can be appreciated, the component values will vary for a given frequency of the RF source, the processing chamber, the power states that are used, and/or other variables that depend on a particular implementation.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An RF matching network connected to an RF generator of a plasma processing system, comprising:
a first RF matching circuit configured to receive an output of a first RF source operating at a first RF frequency;
a second RF matching circuit configured to receive an output of a second RF source operating at a second RF frequency that is greater than the first RF frequency,
wherein the second RF matching circuit includes an impedance transforming circuit configured to operate above resonance and to alter a slope of a tuning space of the second RF matching circuit to reduce reflected power; and
a RF output node in communication with the first RF matching circuit and the second RF matching circuit and an electrode located in a processing chamber of the plasma processing system.

2. The RF matching network of claim 1, wherein the electrode is located in a top plate of an electrostatic chuck.

3. The RF matching network of claim 1, wherein the electrode includes a baseplate of an electrostatic chuck.

4. The RF matching network of claim 1, wherein the impedance transforming circuit includes:
a first impedance including a first terminal connected to the second RF source and a second terminal connected to a reference potential;
a second impedance including a first terminal connected to the second RF source;
a third impedance including a first terminal connected to a second terminal of the second impedance and a second terminal connected to a reference potential;
a fourth impedance including a first terminal connected to the second terminal of the second impedance; and
a fifth impedance including a first terminal connected to the second terminal of the fourth impedance and a second terminal connected to a reference potential.

5. The RF matching network of claim 4, wherein each of the first impedance, the second impedance, the third impedance, the fourth impedance, and the fifth impedance comprise a reactive impedance.

6. The RF matching network of claim 4, wherein:
the first impedance includes a first inductor;
the second impedance includes a first capacitor;
the third impedance includes a second capacitor;
the fourth impedance includes a second inductor; and
the fifth impedance includes a third capacitor.

7. The RF matching network of claim 4, wherein:
the first impedance includes a first inductor;
the second impedance includes a first capacitor;
the third impedance includes a second capacitor;
the fourth impedance includes a third capacitor; and
the fifth impedance includes a second inductor.

8. The RF matching network of claim 4, wherein:
the first impedance includes a first inductor;
the second impedance includes a first capacitor;
the third impedance includes a second capacitor;
the fourth impedance includes a second inductor; and
the fifth impedance includes a third inductor in series with a third capacitor.

9. The RF matching network of claim 1, wherein the first RF matching circuit includes:
a first inductor including a first terminal connected to the first RF source;
a first capacitor including a first terminal connected to a second terminal of the first inductor and a second terminal connected to a reference potential; and
a second inductor including a first terminal connected to the second terminal of the first inductor and to the first terminal of the first capacitor.

10. The RF matching network of claim 9, wherein the first RF matching circuit further includes:
a second capacitor connected to a second terminal of the second inductor;
a third capacitor connected to the second terminal of the second inductor; and
a fourth capacitor connected to the second terminal of the second inductor and a second terminal of the third capacitor.

11. The RF matching network of claim 1, wherein the second RF matching circuit further includes a first capacitor including a first terminal in communication with the impedance transforming circuit and a second terminal in communication with a first terminal of a first impedance.

12. A plasma generator for the plasma processing system, comprising:
the first RF source;
the second RF source;
the RF matching network of claim 1; and
a DC source in communication with the RF output node.

13. The plasma generator of claim 12, wherein the second RF source includes an auto-tuning circuit configured to adjust the second RF frequency in a predetermined frequency band about a center frequency to minimize reflected power.

14. The plasma generator of claim 13, wherein a rate of change of a real component of the resistance of the second RF matching circuit relative to a frequency of the second RF source is greater than zero.

15. The plasma generator of claim 13, wherein the center frequency is 60 MHz and the predetermined frequency band is between 57 MHz and 63 MHz.

16. The plasma generator of claim 12, further comprising:
a first inductance having a first terminal in communication with the DC source and the first RF matching circuit;
a second inductance having a first terminal and a second terminal, wherein the second terminal is connected to the RF output node; and
a third inductance having a first terminal and a second terminal, wherein the first terminal of the third inductance is in communication with the second RF matching circuit and the second terminal of the third inductance is connected to the first terminal of the second inductance.

17. A plasma generator for a plasma processing system, comprising:
a first RF source operating at a first RF frequency;
a first RF matching circuit configured to receive an output of the first RF source;
a second RF source operating at a second RF frequency that is greater than the first RF frequency and including an auto-tuning circuit to adjust the second RF frequency to minimize reflected power;
a second RF matching circuit configured to receive an output of the second RF source and including an impedance transforming circuit configured to operate above resonance and to provide a rate of change of a real component of the resistance of the second RF matching circuit relative to a frequency of the second RF source that is greater than zero; and
a RF output node in communication with the first RF matching circuit and the second RF matching circuit and an electrode located in a processing chamber of the plasma processing system.

18. The plasma generator of claim 17, further comprising a DC source in communication with the RF output node.

19. The plasma generator of claim 17, wherein the electrode is located in a top plate of an electrostatic chuck.

20. The plasma generator of claim 17, wherein the electrode includes a baseplate of an electrostatic chuck.

21. The plasma generator of claim 17, wherein the impedance transforming circuit includes:
a first impedance including a first terminal connected to the second RF source and a second terminal connected to a reference potential;
a second impedance including a first terminal connected to the second RF source;
a third impedance including a first terminal connected to a second terminal of the second impedance and a second terminal connected to a reference potential;
a fourth impedance including a first terminal connected to the second terminal of the second impedance; and
a fifth impedance including a first terminal connected to the second terminal of the fourth impedance and a second terminal connected to a reference potential.

22. The plasma generator of claim 21, wherein each of the first impedance, the second impedance, the third impedance, the fourth impedance, and the fifth impedance comprise a reactive impedance.

23. The plasma generator of claim 21, wherein:
the first impedance includes a first inductor;
the second impedance includes a first capacitor;
the third impedance includes a second capacitor;
the fourth impedance includes a second inductor; and
the fifth impedance includes a third capacitor.

24. The plasma generator of claim 21, wherein:
the first impedance includes a first inductor;
the second impedance includes a first capacitor;
the third impedance includes a second capacitor;
the fourth impedance includes a third capacitor; and
the fifth impedance includes a second inductor.

25. The plasma generator of claim 21, wherein:
the first impedance includes a first inductor;
the second impedance includes a first capacitor;
the third impedance includes a second capacitor;
the fourth impedance includes a second inductor; and
the fifth impedance includes a third inductor in series with a third capacitor.

26. The plasma generator of claim 17, wherein the second RF matching circuit further includes a first capacitor including a first terminal in communication with the impedance transforming circuit and a second terminal in communication with a first terminal of a first impedance.
